(19) United States
(12) Patent Application Publication
(10) Pub. No.: US 2019/0102495 A1
(43) Pub. Date: Apr. 4, 2019

(54) INFORMATION PROCESSING APPARATUS, INFORMATION PROCESSING METHOD, AND PROGRAM

(71) Applicant: SONY CORPORATION, Tokyo (JP)

(72) Inventors: Kazuhiro HONGO, Kanagawa (JP); Takaaki HIRANO, Kanagawa (JP)

(73) Assignee: SONY CORPORATION, Tokyo (JP)

(21) Appl. No.: 16/086,685

(22) PCT Filed: Mar. 31, 2017
(86) PCT No.: PCT/JP2017/013506

§ 371 Date: Sep. 20, 2018

(30) Foreign Application Priority Data
Apr. 14, 2016 (JP) 2016-081032

(51) Int. Cl. G06F 17/50; G06F 17/11; H01L 21/306

(52) U.S. Cl. CPC G06F 17/5018; H01L 21/30625; G06F 17/11; G06F 17/5086

(57) ABSTRACT

The present technology relates to an information processing apparatus, an information processing method, and a program which enable analysis as to what a polishing progress shape looks like, with respect to an external force factor, a polishing object shape, and a material physical property value of a polishing object made up of a plurality of materials. Provided are an acquisition unit configured to acquire structure models corresponding to a second structure as an object to be polished by the first structure; a stress analysis unit configured to analyze a stress exerted on the second structure by the first structure; and a polishing response analysis unit configured to analyze a polishing state of the second structure. The present technology can be applied to an information processing apparatus that analyzes a state of progress of polishing in chemical mechanical polishing.

### TECHNICAL FIELD

The present technology relates to an information processing apparatus, an information processing method, and a program and, for example, to an information processing apparatus, an information processing method, and a program which are configured to analyze what a polishing progress shape looks like in polishing in chemical mechanical polishing, with respect to an external force factor, a polishing object shape, and a material physical property value of a polishing object made up of a plurality of materials.

### BACKGROUND ART

Chemical mechanical polishing is used not only for insulator polishing but also for procedures such as polishing of aluminum and copper wiring and precious metals. The required planarization performance is enhanced as miniaturization encouraged and high precision in its shape prediction technology is also being required.

The following algorithm has been proposed as an approach for analyzing the polishing progress shape. Patent Document 1 has proposed an approach of dividing a circuit into arbitrary unit regions in a mesh shape to work out the wiring density of each mesh region and extracting a region where the wiring density difference between the mesh regions is equal to or greater than a specific condition to return risk feedback as a region where unevenness equal to or greater than a regulation is to be produced.

Patent Document 2 has proposed to have a procedure of generating three-dimensional data for calculation by deforming layout data by a predefined amount and, by quantitative calculation using at least one of the density, the pattern width, and the peripheral length of a wiring pattern of the three-dimensional data, analyzing a pattern predicted to remain as a level difference equal to or greater than a certain degree, and a procedure of reading data of this pattern into a correction unit and correcting the pattern to a layout in which a level difference equal to or greater than a predetermined degree does not remain.

### CITATION LIST

### Patent Document

Patent Document 1: Japanese Patent Application Laid-Open No. 2013-37413
Patent Document 2: Japanese Patent Application Laid-Open No. 2010-272611

### SUMMARY OF THE INVENTION

### Problems to be Solved by the Invention

According to Patent Document 1, since the wiring density calculation is based on wiring pattern mask information, it is impossible to accurately take in the effect of a three-dimensional shape to be actually formed and it is difficult to deal with a case where the process condition is altered. For the reason above, there has been a possibility that versatility and precision would be lowered.

According to Patent Document 2, although a technique is adopted in which a vertical structure is pseudo-constructed from mask information and directly converted into a shape after polishing by mathematical formula processing using a response function, there has been a possibility that the precision is deteriorated by a fitting technique on mathematical formula and it has been difficult to deal with a case where the process condition is altered.

The present technology has been made in view of such a situation and aims to enable analysis as to what a polishing progress shape looks like, with respect to an external force factor, a polishing object shape, and a material physical property value of a polishing object made up of a plurality of materials.

### Solutions to Problems

An information processing apparatus according to one aspect of the present technology includes: an acquisition unit configured to acquire structure models corresponding to a first structure and a second structure as an object to be polished, which is to be polished by the first structure; a stress analysis unit configured to analyze a stress exerted on the second structure by the first structure; and a polishing response analysis unit configured to analyze a polishing state of the second structure by converting a stress and an analyzed region into a region of a density distribution function through analysis by the stress analysis unit and performing analysis based on a diffusion equation.

An information processing method according to one aspect of the present technology includes: a step of acquiring structure models corresponding to a first structure and a second structure as an object to be polished, which is to be polished by the first structure; a step of analyzing a stress exerted on the second structure by the first structure; and a step of analyzing a polishing state of the second structure by converting a stress and an analyzed region into a region of a density distribution function through the analysis and performing analysis based on a diffusion equation.

A program according to one aspect of the present technology causes a computer to execute processes including: a step of acquiring structure models corresponding to a first structure and a second structure as an object to be polished, which is to be polished by the first structure; a step of analyzing a stress exerted on the second structure by the first structure; and a step of analyzing a polishing state of the second structure by converting a stress and an analyzed region into a region of a density distribution function through the analysis and performing analysis based on a diffusion equation.

In the information processing apparatus, the information processing method, and the program according to one aspect of the present technology, structure models corresponding to a first structure and a second structure as an object to be polished, which is to be polished by the first structure, are acquired, a stress exerted on the second structure by the first structure is analyzed, and a polishing state of the second structure is analyzed by converting a stress and an analyzed region into a region of a density distribution function through the analysis and performing analysis based on a diffusion equation.

Note that the information processing apparatus may be an independent apparatus or an internal block constituting one apparatus.

Furthermore, the program can be provided by transmitting the program via a transmission medium or being recorded on a recording medium.

### Effects of the Invention

According to one aspect of the present technology, what a polishing progress shape looks like can be analyzed with respect to an external force factor, a polishing object shape, and a material physical property value of a polishing object made up of a plurality of materials.

Note that the effects described herein are not necessarily limited and any effects described in the present disclosure may be applied.

### BRIEF DESCRIPTION OF DRAWINGS

FIG. 1 is a diagram illustrating the configuration of an information processing apparatus to which the present technology is applied according to an embodiment.

FIG. 2 is a diagram for explaining functions of the information processing apparatus.

FIG. 3 is a flowchart for explaining the operation of the information processing apparatus.

FIG. 4 is a diagram for explaining analysis.

FIG. 5 is a diagram for explaining analysis.

FIG. 6 is a diagram for explaining analysis.

FIG. 7 is a diagram illustrating the relation between a state function and an elastic modulus.

FIG. 8 is a diagram illustrating a screen example.

### MODE FOR CARRYING OUT THE INVENTION

Modes for carrying out the present technology (hereinafter, referred to as embodiments) will be described below. Note that the description will be given in the following order.

1. Configuration of Information Processing Apparatus

2. Functions of Information Processing Apparatus

3. Operation of Information Processing Apparatus

4. About Display of Polishing State

<Configuration of Information Processing Apparatus>

The present technology described below can be applied, for example, to an information processing apparatus that analyzes what a polishing progress shape looks like in polishing in chemical mechanical polishing, with respect to an external force factor, a polishing object shape, and a material physical property value of a polishing object made up of a plurality of materials. Furthermore, the information processing apparatus can be constituted by a personal computer or the like.

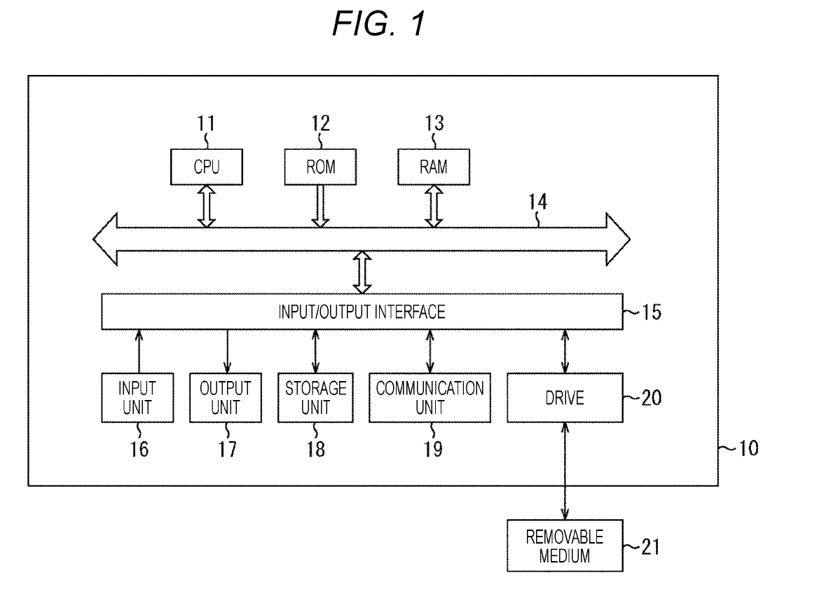

FIG. 1 is a diagram illustrating the configuration of an information processing apparatus to which the present technology is applied according to an embodiment. A central processing unit (CPU) 11, a read only memory (ROM) 12, and a random access memory (RAM) 13 of the information processing apparatus 10 illustrated in FIG. 1 are interconnected by a bus 14. Moreover, an input/output interface 15 is connected to the bus 14. An input unit 16, an output unit 17, a storage unit 18, a communication unit 19, and a drive 20 are connected to the input/output interface 15.

The input unit 16 includes a keyboard, a mouse, a microphone and the like. The output unit 17 includes a display, a speaker and the like. The storage unit 18 includes a hard disk, a non-volatile memory and the like. The communication unit 19 includes a network interface and the like. The drive 20 drives a removable medium 21 such as a magnetic disk, an optical disc, a magneto-optical disk, or a semiconductor memory.

<Functions of Information Processing Apparatus>

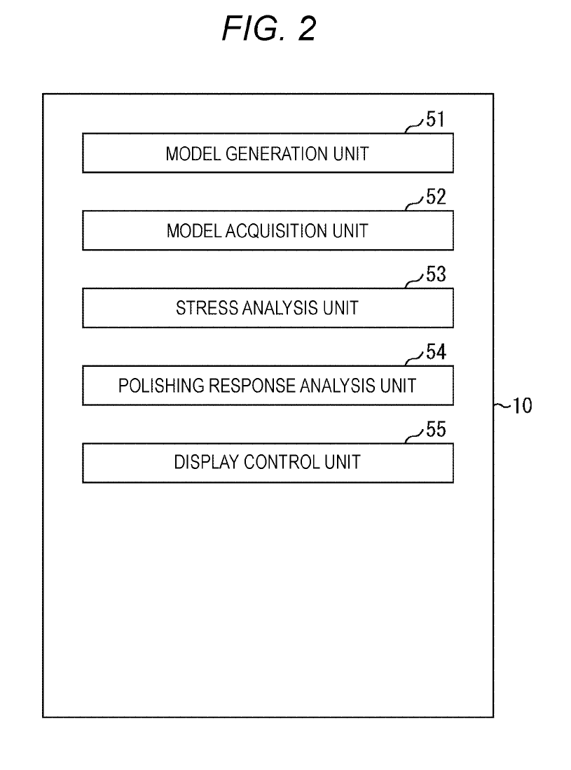

FIG. 2 is a diagram for explaining functions included in the information processing apparatus 10. Each function illustrated in FIG. 2 may be a function implemented as hardware by the information processing apparatus 10, or may be a function implemented by the information processing apparatus 10 (CPU 11) executing a program.

A model generation unit 51 generates a model to be analyzed. The information processing apparatus 10 is an apparatus configured to analyze what a polishing progress shape looks like in polishing in chemical mechanical polishing, with respect to an external force factor, a polishing object shape, and a material physical property value of a polishing object including a plurality of materials and a wafer model to be analyzed by the information processing apparatus 10 is generated by the model generation unit 51.

A model acquisition unit 52 acquires a model generated by the model generation unit 51 or a model supplied from the outside. Note that, in a case where a model is supplied from the outside, it is also possible to employ a configuration that does not have the model generation unit 51.

A stress analysis unit 53 carries out stress analysis in a manner mimicking a polishing operation. According to stress distributions of various materials obtained as a result of the analysis by the stress analysis unit 53, a polishing response analysis unit 54 performs polishing response analysis on the basis of a mathematical formula of the phase field method describing that the opening of energy occurs by first polishing a higher stress region of a boundary surface with a chemical mechanical polishing pad and a system goes to a low energy state as a whole.

A display control unit 55 controls display on a display constituting the output unit 17 (FIG. 1) and, for example, controls the display of a result of the analysis by the polishing response analysis unit 54.

<Operation of Information Processing Apparatus>

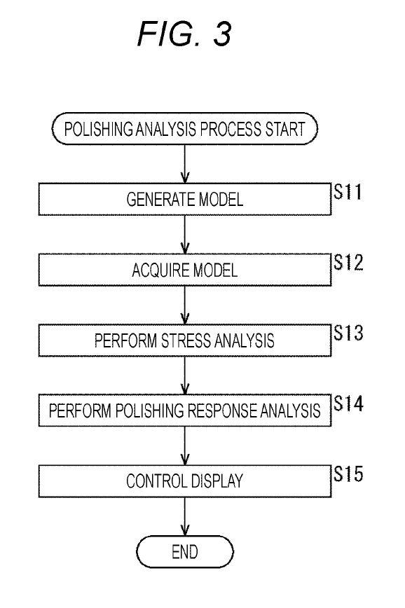

Processes relating to a polishing analysis process of the information processing apparatus 10 illustrated in FIGS. 1 and 2 will be described with reference to a flowchart illustrated in FIG. 3.

In step S11, a model (wafer model) is generated by the model generation unit 51 (FIG. 2). Here, an explanation will be given taking as an example a case of analysis when an insulator coated on a wafer is polished by a chemical mechanical polishing pad.

Here, the case of analyzing structure models (wafer model) corresponding to a first structure (chemical mechanical polishing pad) and a second structure (insulator) as an object to be polished, which is to be polished by this first structure, will be described as an example. However, the present technology can be applied to the case of analyzing a structure model relating to a plurality of structures and also can be applied to a model other than the structure model relating to polishing.

In step S11, a three-dimensional shape of the insulating band coated on the wafer before chemical mechanical polishing is modeled with high precision.

It is possible to model a three-dimensional shape from mask data using a simulation application for accurately predicting shape response by a process such as thin film deposition, sputtering, and etching in a wafer process.

Alternatively, a surface shape and a cross-sectional shape of the actually created wafer may be observed such that shape data is acquired and a three-dimensional shape is created according to the shape data using a modeling tool.

Furthermore, in a case where, for example, data of an already generated model is acquired from the outside, the process in step S11 can be omitted.

In step S12, the model generated in step S11 is acquired by the model acquisition unit 52 (FIG. 2). Note that, in a case where the model is generated by the model generation unit 51, the model is acquired from the model generation unit 51 and, in a case where a model is supplied from an external device or the like, the model is acquired from this external device.

In step S13, the stress analysis unit 53 (FIG. 2) executes stress analysis. The stress analysis unit 53 prepares the wafer model with the three-dimensional shape acquired by the model acquisition unit 52 and a model of the chemical mechanical polishing pad and carries out the stress analysis in a manner mimicking an actual polishing operation. In this case, a stress exerted on the second structure (insulator) by the first structure (chemical mechanical polishing pad) is analyzed.

The stress analysis unit 53 is configured to be able to prepare models of a plurality of chemical mechanical polishing pads. For example, the stress analysis unit 53 holds the elastic moduli and the Poisson's ratios of a plurality of chemical mechanical polishing pads for each pad and reads information regarding a pad to be applied by following the instruction of a user, to prepare a model of the chemical mechanical polishing pad.

A finite element method (FEM) can be used for the stress analysis. Since the finite element method can deal with arbitrary shapes and has high versatility, the explanation will be continued here on the assumption that the stress analysis is performed by the FEM.

The state of distribution of stress in the wafer model having the three-dimensional shape can be grasped by the processes so far.

In step S14, according to the stress distributions of various materials obtained in step S13, the polishing response analysis unit 54 performs polishing response analysis on the basis of a mathematical formula of the phase field method describing that the opening of energy occurs by first polishing a higher stress region of a boundary surface with the chemical mechanical polishing pad and a system goes to a low energy state as a whole.

In step S15, a polishing response analysis result obtained in step S14 is displayed on a display (not illustrated) by the display control unit 55 (FIG. 2).

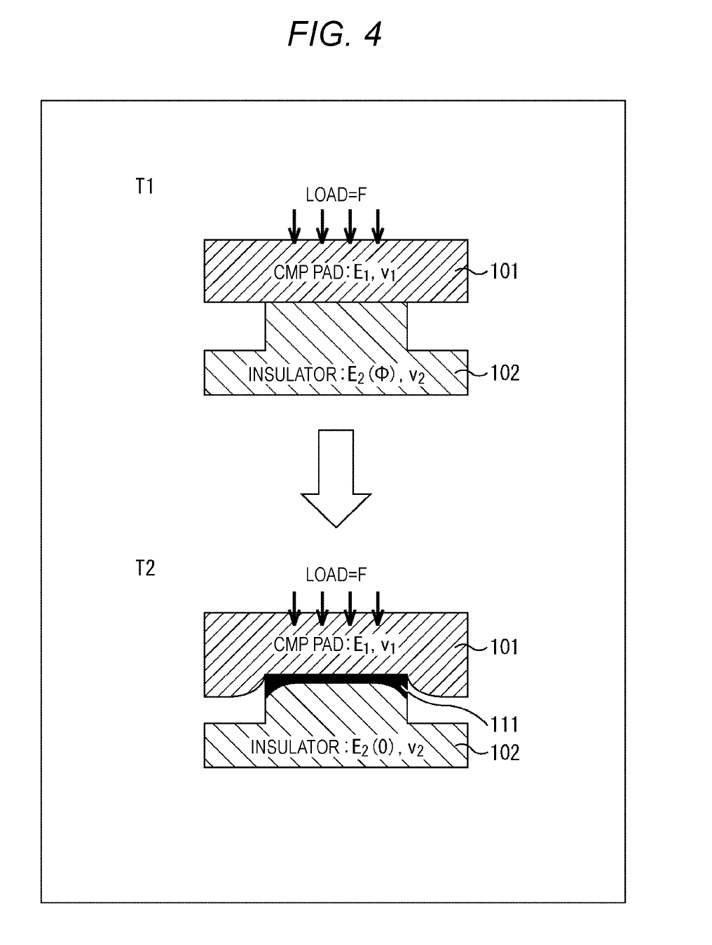

The above-described analysis processes will be further described with reference to FIGS. 4 to 6. FIGS. 4 to 6 represent image diagrams for the analysis processes.

The upper diagram of FIG. 4 is a diagram representing a wafer model (a wafer model in the initial state) at a time point T1, representing the wafer model generated in step S11 and acquired in step S12. A state at the time point T1 is such that an insulator 102 is coated on the wafer and, in order to planarize this insulator 102, a chemical mechanical polishing pad (written as CMP pad in FIG. 4) 101 is positioned on the insulator 102.

In this manner, the chemical mechanical polishing pad and the object to be polished are modeled on a simulation. Furthermore, during modeling, the elastic modulus and the Poisson's ratio in accordance with the characteristics of each material are defined for each element and a load in accordance with a pressure condition for a polishing procedure is also set.

In the drawings and the following description, E represents the elastic modulus and V represents the Poisson's ratio. In addition, ϕ represents a state function, where a state function ϕ=0 is a function representing a state before polishing and a state function ϕ=1 is a function representing a polished state. Furthermore, the elastic modulus of the chemical mechanical polishing pad 101 is assigned as E1 and the Poisson's ratio thereof is assigned as V1. Additionally, the elastic modulus of the insulator 102 is assigned as E2 and the Poisson's ratio thereof is assigned as V2.

As the time point T1 (initial state), assuming a state before polishing, the state functions ϕ of respective elements are all defined to be zero. In other words, at the time point T1 in FIG. 4, the state function ϕϕ of the insulator 102 is zero.

A time point T2 in FIG. 4 indicates a state in which the stress analysis by the FEM has been carried out on such a wafer model (a state in which the process in step S13 has been executed). The time point T2 when the stress analysis has been executed is in a state in which the chemical mechanical polishing pad 101 is pressed against the insulator 102 and polishing is to be started and, in this state, the chemical mechanical polishing pad 101 is pressed against the insulator 102 such that a stress is applied to the insulator 102.

A region where the stress applied to the insulator 102 is distributed (referred to as a stress distribution region 111) is analyzed through the stress analysis by the FEM. It can be seen that a larger stress is applied to corner portions of a convex portion of the insulator 102 than a central portion. Furthermore, the chemical mechanical polishing pad 101 also undergoes a deformation in which a portion touching the convex portion of the insulator 102 is recessed. In addition, in the state at the time point T2, the state function ϕ of the insulator 102 is zero.

In this manner, the stress and strain applied to the insulator 102 (second structure) by the chemical mechanical polishing pad 101 (first structure) are calculated.

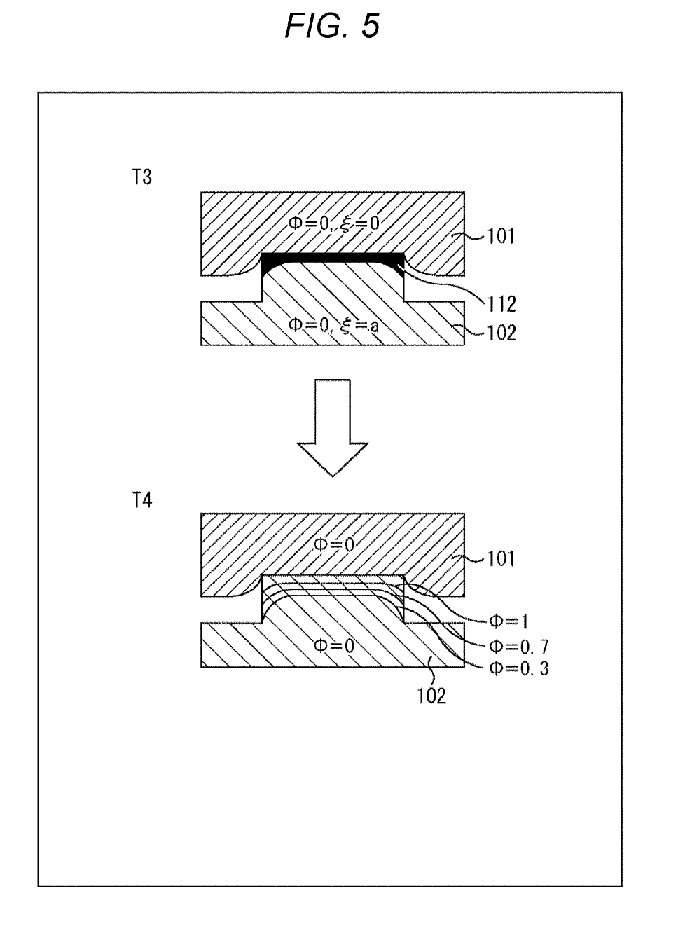

At a next time point T3 (FIG. 5), the stress distribution region 111 is replaced with a region of calorification Q (referred to as a calorific region 112). Heat transfer analysis by the FEM is performed (polishing stress analysis in step S14 is performed) on the wafer model at the time point T3. The heat transfer analysis by the FEM (the polishing stress analysis by the FEM) is performed on the basis of the following formula (1).

$$\begin{matrix}[ Mathematical Formula 1 ] & \\ \frac{1}{M} \frac{\partial φ}{\partial t} = ∇ ( ɛ ∇ φ ) - ( \frac{\partial {f}_{doub}}{\partial φ} + \frac{\partial {f}_{elast}}{\partial φ} ) & ( 1 )\end{matrix}$$

Formula (1) is an example of a governing equation used in the polishing response analysis. In formula (1), ϕ denotes the above-described state variable, which is a variable representing states from a state before polishing until a polished state. For example, ϕ=0 indicates that an applicable element is in a state before polishing and ϕ=1 indicates that an applicable element is in a polished state (lost state), while ϕ between 0 and 1 indicates that an applicable element is in the middle of the course.

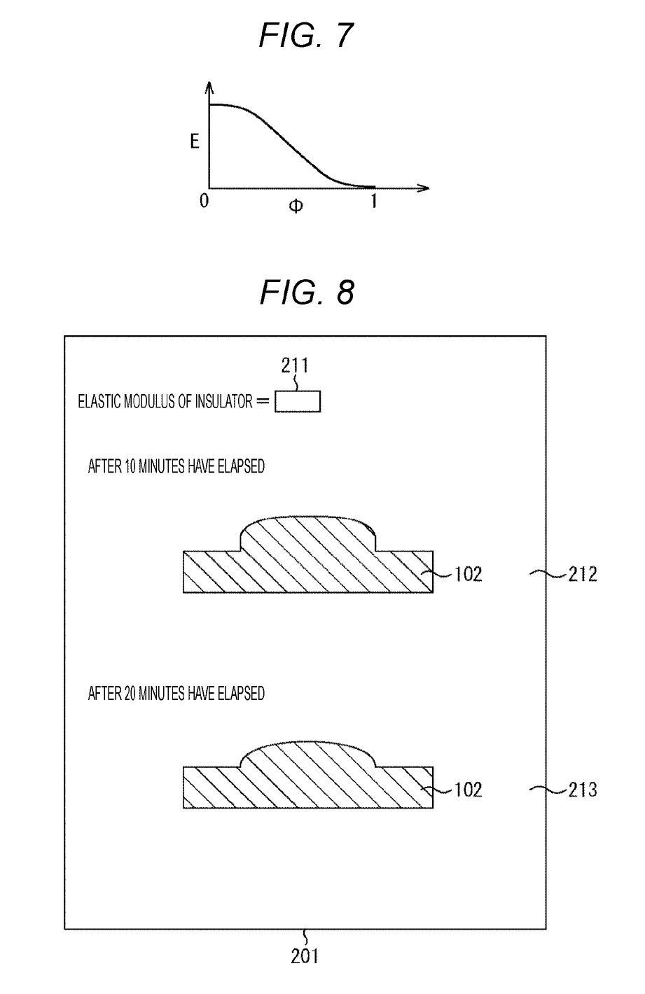

For example, the relation between the state function ϕ and the elastic modulus E has a relation as illustrated in FIG. 7. In the graph illustrated in FIG. 7, the horizontal axis represents the state function ϕ and the vertical axis represents the elastic modulus E. As illustrated in FIG. 7, it is characteristic that the elastic modulus inherent to the material is defined at ϕ=0 before polishing and zero or a very small value is defined in the polished state with ϕ=1. A polishing surface is constantly pressurized by a predetermined degree during polishing and, for a polished region, a shape after polishing is expressed by being depressed with the reception of this pressure.

The first term (left side) of the governing equation (formula (1)) is a time derivative term of the state function ϕ, where M is a constant thereof. The first term is a term representing how much the polishing advances with respect to time.

The second term (the first term on the right side) is a term for spatial second-order derivative with respect to the state function ϕ, while f_{doub} in the third term (the second term on the right side) is associated with potential energy and the entire third term a term representing energy necessary for a state change in the state function ϕ. fₑₗₐₛₜ in the fourth term (the third term on the right side) is associated with elastic energy and the entire fourth term is a term representing elastic energy released at the time of state change.

In other words, the governing equation indicated formula (1) calculates a variable (state function ϕ) expressing a polishing state defined for each spatial point and the energy opening rate of a material having the elastic characteristic depending on the variable and is a differential equation having a term for time derivative of the variable, a term proportional to the spatial second-order derivative of the variable, and a term proportional to the energy opening rate.

Meanwhile, a well-known heat transfer equation is given by the following formula (2).

$$\begin{matrix}[ Mathematical Formula 2 ] & \\ {C}_{v} \frac{\partial T}{\partial t} = λ {∇}^{2} T + Q & ( 2 )\end{matrix}$$

In formula (2), Cv represents a unit volume heat capacity (J/(m³·K)), λ represents a heat transfer rate (W/(m/K)), T represents a temperature (K), and Q represents a calorific value (W/m³). The relation indicated in formula (2) is defined for each material.

Formula (2) is made up of a time derivative term with respect to the temperature in the first term (left side), a term for spatial second-order derivative with respect to the temperature in the second term (the first term on the right side), and a term for calorific value in the third term (the second term on the right side) and is an equation equivalent to the differential equation in formula (1).

This means that analysis based on the equation of formula (1) is possible using a solver for heat transfer analysis by matching the state function ϕ in formula (1) with the temperature T in formula (2) and matching the third term and the fourth term of formula (1) with the third term of formula (2).

Furthermore, since the diffusion equation also has a similar form of differential equation, a solver for diffusion equation also can be used. Since a large number of solvers for heat transfer/diffusion analysis are ready for both commercial and non-commercial use and have been fully developed, it is exceptionally advantageous that such solvers can be utilized appropriately for analysis.

Note that the example described here, in which the stress distribution region 111 is replaced with the calorific region 112 and the heat transfer analysis is performed by the FEM, is an example of analyzing the polishing state by converting the stress distribution region 111 into the density distribution function region and performing analysis based on the diffusion equation. In other words, the explanation will be made here by giving an example in which the calorific value distribution is used as the density distribution function and the heat transfer equation is used as the diffusion equation. Also the following explanation will be similarly made.

However, the present technology also can be applied to a case using a distribution function other than the calorific value distribution as the density distribution function and also can be applied to a case of analysis using an equation other than the heat transfer equation as the diffusion equation.

Returning to the explanation with reference to FIG. 5, by replacing the stress distribution region 111 with the calorific region 112 and performing the polishing stress analysis based on formula (1) (the heat transfer analysis based on formula (2)) at the time point T3, an analysis result as indicated by a time point T4 is obtained.

When the analysis based on formula (1) or (2) is performed at the time point T3, the state function ϕ of the chemical mechanical polishing pad 101 is assigned as zero and the polishing rate ξ thereof is assigned as zero, and the state function ϕ of the insulator 102 is assigned as zero and the polishing rate thereof is assigned as ξ=a, to perform a mathematical operation.

Note that the polishing rate ξ (diffusion constant) relating to the second term of formula (1) can be defined as the easiness of polishing of the material. On the heat transfer equation (formula (2)), the polishing rate ξ is a parameter associated with the heat transfer rate and is decided depending on a material to be polished, slurry, pad conditions, and the like.

Furthermore, the polishing rate ξ may be defined so as to have direction dependence in space. With this configuration, anisotropic polishing response depending on process conditions for a semiconductor apparatus can be expressed, for example, a crystalline body or a porous structure as an object to be polished, a difference in degree of density between a planar portion and a side wall portion, and anisotropy of chemical response of the slurry.

In this manner, the fourth term (the third term on the right side) of formula (1) is calculated using the result of stress or strain of each element. Since the third term (the second term on the right side) of formula (1) is also uniquely calculated by materials, a value associated with the third term (the second term on the right side) of formula (2) can be found.

With this calculation, a value associated with the calorific value Q in formula (2) is defined, such that each parameter in formula (1) is replaced with each parameter in formula (2) as described above and transient analysis after a certain time has elapsed is performed using a solver based on the heat transfer equation, as a diffusion problem of the state function ϕ.

In this manner, a distribution of the state function ϕ is obtained (time point T4). Referring to the wafer model at the time point T4 in FIG. 5, the state function ϕ is one on a side close to a surface of the convex portion (a portion assigned as a polishing object) of the insulator 102 (a side touching the chemical mechanical polishing pad 101) and the analysis result that the polished state has been brought about is obtained.

The analysis result indicating the state function ϕ=0.7 is obtained on a lower side of the state function ϕ=1 and the analysis result indicating the state function ϕ=0.3 is obtained on a still lower side. Moreover, a lower side of the state function ϕ=0.3 has the state function ϕ=0 and the analysis result that it is in a state before polishing is obtained.

As described above, it is possible to analyze the polishing state of the wafer model, for example, how much the polishing proceeds or what shape the shape after polishing will have, when a predetermined time from the start of polishing, in this case, the time from the time point T1 to the time point T4 has elapsed.

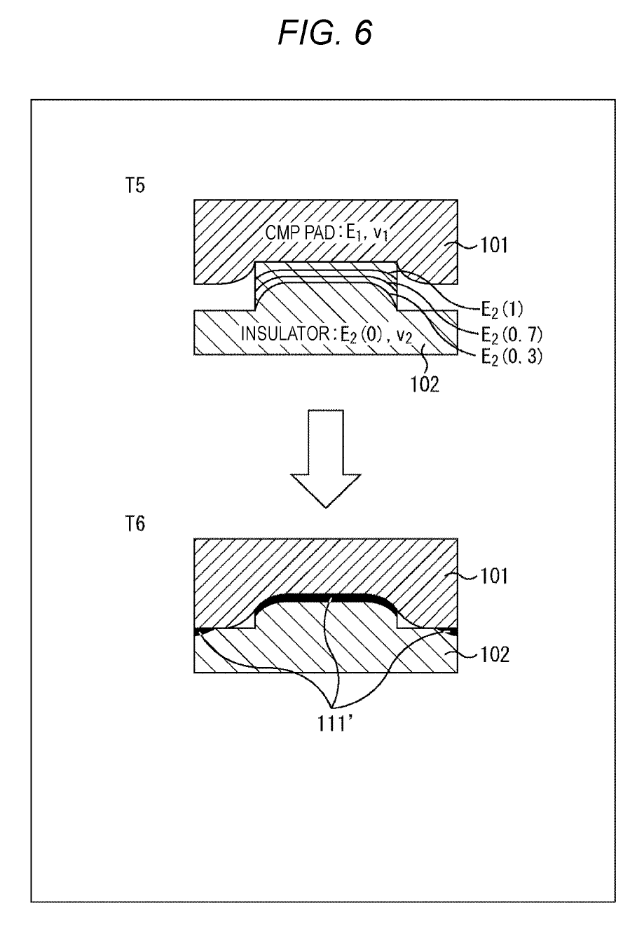

Moreover, the state function ϕ is replaced with the elastic modulus E when the state at the time point T4 shifts to a state at a time point T5 (FIG. 6). As illustrated in FIG. 7, the state function ϕ and the elastic modulus E has a predetermined relationship and the state function ϕ can be converted into the elastic modulus E by utilizing the relationship therebetween. As indicated by the time point T5 in FIG. 6, the state function ϕ=1 of the insulator 102 is converted into an elastic modulus E2(1), the state function ϕ=0.7 is converted into an elastic modulus E2(0.7), and the state function ϕ=0.3 is converted into an elastic modulus E2(0.3), and the state function ϕ=0 is converted into an elastic modulus E2(0).

In such a wafer model, the state represented by the elastic modulus E is the same as the state indicated by the time point T1 (FIG. 4). However, since this state is after the polishing has been already executed, the difference therebetween is that the value (E(ϕ)) of the elastic modulus E of each material also has changed as a consequence of a change in the value of the state function ϕ.

The stress analysis by the FEM is carried out again for the state of the wafer model at the time point T5. This analysis can be performed in a similar manner to when the stress analysis by the FEM is executed for the wafer model state at the time point T1. In other words, the stress analysis can be performed on the wafer model that has been polished for a predetermined time. In different terms, it is possible to confirm the state of polishing in the course of polishing and to simulate how the state will proceed in a case where further polishing is continued.

The wafer model after the stress analysis has been executed again is indicated by a time point T6 in FIG. 6. The elastic modulus E of an element in the polished state or approaching that state is deteriorated as a consequence of a change in the state function ϕ, while the convex portion of the insulator 102 is depressed by the pressure of the chemical mechanical polishing pad 101 and changes to a different shape from that at the time point T2 (FIG. 4).

Furthermore, in the wafer model indicated by the time point T6 in FIG. 6, it is analyzed that, since the convex portion of the insulator 102 has been polished and depressed by the pressure, the chemical mechanical polishing pad 101 also makes contact with portions of the insulator 102 other than the convex portion and a stress is applied. In other words, in this case, it is analyzed that stress distribution regions 111′ are produced not only in the convex portion of the insulator 102 but also in a region other than the convex portion.

In this manner, as the shape changes, a contact or non-contact state of each region changes and stress and strain states change. Then, according to the present technology, it is possible to obtain a result of stress and strain distributions in agreement with a shape in which polishing has progressed.

Since the wafer model at the time point T6 is in a state in which the stress distribution is obtained as with the wafer model at the time point T2, a wafer model in a further polished state can be obtained by performing the heat transfer analysis (polishing response analysis) on the wafer model at the time point T6, as in the case of the wafer model at the time point T2.

After the analysis described above, that is, the transient response analysis by the differential equation is advanced to a certain time, the stress analysis for taking in a change in the variable as a result of the above analysis and calculating the energy opening rate is carried out and a result of this stress analysis is reflected to the differential equation to repeat transient response analysis similar to the aforementioned one, whereby it is possible to transiently carry out highly precise polishing response analysis while considering the influence of the shape change.

Incidentally, the elastic modulus of an element judged to be in a polished state is greatly deteriorated and a large deformation occurs under pressure. In a general solver for analysis, when a shape deformed to a certain degree or larger from an initial shape or a shape with a high aspect ratio is reached, there is a possibility of leading to the degradation of the precision of calculation and the convergence.

Thus, in order to prevent such difficulties in advance, a process may be included, in which, when the strain and deformation of an element in a calculation region reaches a certain amount, an algorithm that reconstructs a mesh is added such that the degradation of the precision of calculation and the convergence is not produced.

Furthermore, the judgment criteria for reconstruction may be common to all materials or may be defined for each material. In the above example, a common judgment criterion may be used for the first structure and the second structure (the chemical mechanical polishing pad 101 and the insulator 102), or different judgment criterion may be separately used for the first structure and the second structure.

In the above-described embodiment, the case of analyzing the insulator 102 has been described as an example, but also the chemical mechanical polishing pad 101 may be additionally analyzed or the chemical mechanical polishing pad 101 may be analyzed. By defining the state function ϕ and the elastic modulus E for the chemical mechanical polishing pad 101 and performing analysis equivalent to the above analysis, it is possible to analyze a depression amount and a polishing amount of the chemical mechanical polishing pad 101.

Furthermore, although formulas (1) and (2) are exemplified in the above-described embodiment, formulas (1) and (2) are basic equations and another term may be added so as to be able to deal with an additional phenomenon. In addition, it is also possible to transform the formula into a format for multiplying the entire formula (1) or (2) by a certain constant or dividing the entire formula (1) or (2) by a certain constant, to apply to the present technology.

According to the present technology, high precision can be achieved by structure reproduction modeling of the structure of an object to be polished. Furthermore, high versatility can be achieved by response analysis on a stress value as an analysis result by the FEM. In addition, end-to-end analysis covering from the stress analysis to the polishing response analysis is possible.

Furthermore, the polishing response analysis can significantly shorten the calculation time by coupled analysis with the heat transfer equation or the diffusion equation. In addition, it is possible to perform a repetitive process of the response analysis with increments of constant or variable time, such that highly precise analysis in consideration of the influence of a change while being in a contact or non-contact state due to shape change is enabled. Moreover, also the polishing amount of the chemical mechanical polishing pad can be analyzed.

<About Display of Polishing State>

As described above, according to the present technology, analysis from the start to the end of polishing including intermediate results is possible. In other words, according to the present technology, it is possible to obtain states of the wafer model from the start of polishing to when polishing has been carried on for a predetermined time.

For example, the time point T1 (FIG. 4) depicts a state before the start of polishing and the time point T6 (FIG. 6) indicates a state after polishing for a predetermined time. According to the present technology, it is possible to provide a wafer model before the start of polishing to the user, or to provide a wafer model after polishing for a predetermined time to the user.

FIG. 8 illustrates a screen example in the case of providing the user with a wafer model after polishing for a predetermined time. The screen example illustrated in FIG. 8 indicates an example in which a shape of the insulator 102 when 10 minutes have elapsed from the start of polishing and a shape of the insulator 102 when 20 minutes have elapsed from the start of polishing are displayed on a display 201 constituting the output unit 17 (FIG. 1) of the information processing apparatus 10.

A field 211 in which the elastic modulus of the insulator can be input is arranged at an upper part of the screen of the display 201 and the above-described analysis is performed with a value input in this field 211. A field for inputting another value of course may be displayed. Furthermore, a field in which the type of the chemical mechanical polishing pad 101 can be selected, or the like may be displayed.

Arranged on a lower side of the field 211 is a display portion 212 on which a model representing the polishing state of the insulator 102 after 10 minutes have elapsed from the start of polishing is displayed. Moreover, arranged on a lower side of the display portion 212 is a display portion 213 on which a model representing the polishing state of the insulator 102 after 20 minutes have elapsed from the start of polishing is displayed.

The models displayed on the display portions 212 and 213 are models obtained as results of the analysis as described above. The models displayed on the display portions 212 and 213 are not restricted to ones after time such as 10 minutes and 20 minutes but, for example, a model after time specified by the user is displayed. Furthermore, slideshow may be enabled such that changes in polishing state can be confirmed as time elapses. Alternatively, models may be presented to the user with an animation in which changes in polishing state can be confirmed as time elapses.

By referring to such a screen, the user can confirm the polishing state with the lapse of time. Since the polishing state can be confirmed in such a manner, for example, an appropriate polishing time can be examined. In different terms, it is possible to decide the time until the insulator 102 is polished to a desired film pressure or shape, while confirming the elapsed time from the start of polishing and the models which are the analysis results.

Furthermore, since the state of polishing can be confirmed at the wafer level, for example, it is also possible to detect a region difficult to polish and to examine countermeasures therefor. For example, it is possible to examine polishing by another polishing technique such as resist etching after polishing a region difficult to polish only for a predetermined time. Furthermore, it is also possible to examine polishing individually performed on regions difficult to polish after polishing the entire wafer. In addition, at the time of such examination, the screen as illustrated in FIG. 8 can be referred to during the examination.

Furthermore, since the polishing situation with the lapse of time can be confirmed, it is also possible to examine, for example, how the state will proceed if polishing methods with different conditions are combined. For example, in a case where polishing using a chemical mechanical polishing pad A is carried on for a predetermined time and, thereafter, polishing with a chemical mechanical polishing pad B different from the chemical mechanical polishing pad A is performed, how the polishing situation changes can be confirmed according to the present technology. Accordingly, the present technology can be used, for example, for examining an efficient combination of polishing methods, and the like.

<About Recording Medium>

A series of the above-described processes can be executed by hardware as well and also can be executed by software. In a case where the series of the processes is executed by software, a program constituting the software is installed in a computer. Here, the computer includes a computer built into dedicated hardware and a computer capable of executing various functions when installed with various programs, for example, a general-purpose personal computer, or the like.

For example, the program executed by the information processing apparatus 10 (CPU 11) can be provided by being recorded in the removable medium 21 serving as a package medium or the like. Furthermore, the program can be provided via a wired or wireless transmission medium such as a local area network, the Internet, or digital satellite broadcasting.

In the information processing apparatus 10, the program can be installed to the storage unit 18 via the input/output interface 15 by mounting the removable medium 21 in the drive 20. Furthermore, the program can be installed to the storage unit 18 via a wired or wireless transmission medium when received by the communication unit 19. As an alternative manner, the program can be installed to the ROM 12 or the storage unit 18 in advance.

Note that, the program executed by a computer may be a program in which the processes are performed along the time series in line with the order described in the present description, or alternatively, may be a program in which the processes are performed in parallel or at a necessary timing, for example, when called.

Furthermore, in the present description, the term “system” represents the entire apparatus constituted by a plurality of apparatuses.

Note that the effects described in the present description merely serve as examples and not construed to be limited. There may be another effect as well.

Note that the present technology can also be configured as follows.

(1)

An information processing apparatus including:

an acquisition unit configured to acquire structure models corresponding to a first structure and a second structure as an object to be polished, which is to be polished by the first structure;

a stress analysis unit configured to analyze a stress exerted on the second structure by the first structure; and

a polishing response analysis unit configured to analyze a polishing state of the second structure by converting a stress and an analyzed region into a region of a density distribution function through analysis by the stress analysis unit and performing analysis based on a diffusion equation.

(2)

The information processing apparatus according to claim 1, in which

the density distribution function is replaced with a calorific value distribution, the diffusion equation is replaced with a heat transfer equation, and a polishing state is analyzed by heat transfer analysis.

(3)

The information processing apparatus according to (1) or (2) above, in which

a state of progress of polishing in chemical mechanical polishing is analyzed.

(4)

The information processing apparatus according to any one of (1) to (3) above, in which

the stress analysis unit performs analysis by a finite element method (FEM).

(5)

The information processing apparatus according to any one of (1) to (4) above, in which

the polishing response analysis unit performs analysis by a finite element method (FEM).

(6)

The information processing apparatus according to any one of (1) to (5) above, in which

the polishing response analysis unit calculates a variable expressing a polishing state defined for each spatial point and an energy opening rate of a material having an elastic characteristic depending on the variable, and

the polishing response analysis unit calculates a differential equation having a term for time derivative of the variable, a term proportional to spatial second-order derivative of the variable, and a term proportional to the energy opening rate.

(7)

The information processing apparatus according to (6) above, in which

a proportionality constant relating to a term for spatial second-order derivative of the variable is defined as a parameter correlated with easiness of polishing of each material.

(8)

The information processing apparatus according to (7) above, in which

the parameter is defined so as to have direction dependence in space.

(9)

The information processing apparatus according to (6) above, in which

in stress calculation for calculating the energy opening rate, a mesh is reconfigured in a case where a volume change rate of an element in a calculation region becomes equal to or greater than a certain value.

(10)

The information processing apparatus according to (6) above, in which

after transient response analysis by the differential equation is advanced to a certain time, stress analysis for taking in a change in a variable as a result of the transient response analysis and calculating an energy opening rate is carried out and a result of this stress analysis is reflected to the differential equation to repeat transient response analysis similar to the aforementioned transient response analysis.

(11)

An information processing method including:

a step of acquiring structure models corresponding to a first structure and a second structure as an object to be polished, which is to be polished by the first structure;

a step of analyzing a stress exerted on the second structure by the first structure; and

a step of analyzing a polishing state of the second structure by converting a stress and an analyzed region into a region of a density distribution function through the analysis and performing analysis based on a diffusion equation.

(12)

A program for causing a computer to execute processes including:

a step of acquiring structure models corresponding to a first structure and a second structure as an object to be polished, which is to be polished by the first structure;

a step of analyzing a stress exerted on the second structure by the first structure; and

a step of analyzing a polishing state of the second structure by converting a stress and an analyzed region into a region of a density distribution function through the analysis and performing analysis based on a diffusion equation.

### REFERENCE SIGNS LIST

10 Information processing apparatus
51 Model generation unit
52 Model acquisition unit
53 Stress analysis unit
54 Polishing response analysis unit
55 Display control unit
101 Chemical mechanical polishing pad
102 Insulator
111 Stress distribution region
112 Calorific region
201 Display
211 Field
212, 213 Display portion

What is claimed is:

1. An information processing apparatus comprising:
an acquisition unit configured to acquire structure models corresponding to a first structure and a second structure as an object to be polished, which is to be polished by the first structure;
a stress analysis unit configured to analyze a stress exerted on the second structure by the first structure; and
a polishing response analysis unit configured to analyze a polishing state of the second structure by converting a stress and an analyzed region into a region of a density distribution function through analysis by the stress analysis unit and performing analysis based on a diffusion equation.

2. The information processing apparatus according to claim 1, wherein the density distribution function is replaced with a calorific value distribution, the diffusion equation is replaced with a heat transfer equation, and a polishing state is analyzed by heat transfer analysis.

3. The information processing apparatus according to claim 1, wherein a state of progress of polishing in chemical mechanical polishing is analyzed.

4. The information processing apparatus according to claim 1, wherein the stress analysis unit performs analysis by a finite element method (FEM).

5. The information processing apparatus according to claim 1, wherein the polishing response analysis unit performs analysis by a finite element method (FEM).

6. The information processing apparatus according to claim 1, wherein
the polishing response analysis unit calculates a variable expressing a polishing state defined for each spatial point and an energy opening rate of a material having an elastic characteristic depending on the variable, and
the polishing response analysis unit calculates a differential equation having a term for time derivative of the variable, a term proportional to spatial second-order derivative of the variable, and a term proportional to the energy opening rate.

7. The information processing apparatus according to claim 6, wherein a proportionality constant relating to a term for spatial second-order derivative of the variable is defined as a parameter correlated with easiness of polishing of each material.

8. The information processing apparatus according to claim 7, wherein the parameter is defined so as to have direction dependence in space.

9. The information processing apparatus according to claim 6, wherein in stress calculation for calculating the energy opening rate, a mesh is reconfigured in a case where a volume change rate of an element in a calculation region becomes equal to or greater than a certain value.

10. The information processing apparatus according to claim 6, wherein after transient response analysis by the differential equation is advanced to a certain time, stress analysis for taking in a change in a variable as a result of the transient response analysis and calculating an energy opening rate is carried out and a result of this stress analysis is reflected to the differential equation to repeat transient response analysis similar to the aforementioned transient response analysis.

11. An information processing method comprising:
a step of acquiring structure models corresponding to a first structure and a second structure as an object to be polished, which is to be polished by the first structure;
a step of analyzing a stress exerted on the second structure by the first structure; and
a step of analyzing a polishing state of the second structure by converting a stress and an analyzed region into a region of a density distribution function through the analysis and performing analysis based on a diffusion equation.

12. A program for causing a computer to execute processes comprising:
a step of acquiring structure models corresponding to a first structure and a second structure as an object to be polished, which is to be polished by the first structure;
a step of analyzing a stress exerted on the second structure by the first structure; and
a step of analyzing a polishing state of the second structure by converting a stress and an analyzed region into a region of a density distribution function through the analysis and performing analysis based on a diffusion equation.
